(19) United States
(12) Patent Application Publication
(10) Pub. No.: US 2007/0216455 A1
(43) Pub. Date: Sep. 20, 2007

(54) Partial cascode delay locked loop architecture

(75) Inventor: Saeed Abbasi, Narberth, PA (US)

Correspondence Address: Tyco Electronics Corporation, Suite 140, 4550 New Linden Hill Road, Wilmington, DE, 19808-2952, US

(73) Assignee: M/A-COM, Inc.

(21) Appl. No.: 11/378,828

(22) Filed: Mar. 17, 2006

(51) Int. Cl. H03L 7/06

(52) U.S. Cl. 327/158

(57) ABSTRACT

Various embodiments for a partial cascode delay locked loop architecture are described. In one embodiment, an apparatus may include a delay locked loop circuit having a plurality of partial cascode circuits. The plurality of partial cascode circuits may be arranged to reduce phase noise from a ground power supply voltage and a power supply voltage. Other embodiments are described and claimed.

This application is related to U.S. patent application Ser. No. 11/325,766, which was filed on Jan. 4, 2006 and U.S. patent application Ser. No. 11/186,000, which was filed on Jul. 20, 2005. These applications are incorporated by reference.

### BACKGROUND

Delay-locked loop (DLL) circuits are often used to reduce noise and improve timing throughout a circuit. Timing throughout a circuit becomes particularly critical for applications requiring high-speed processing of information, such as in communications applications and video processing applications. When noise is introduced by various system components, the timing may deviate from the system clock.

Variations in power supplies may increase noise and have a significant impact on overall system performance. Several shortcomings in the conventional DLL circuit lead to a low Power Supply Rejection Ratio (PSRR) in analog cells. Lower PSRR leads to higher phase noise in the DLL, which is not desirable for processing applications. Accordingly, there is a need for a DLL circuit that provides improved PSRR.

### SUMMARY

One embodiment may include an apparatus comprising a delay locked loop circuit. The delay locked loop circuit may comprise a plurality of partial cascode circuits. The plurality of partial cascode circuits may include at least a first partial cascode circuit and a second partial cascode circuit. The first partial cascode circuit may be driven by a first bias voltage and may be connected to a ground supply voltage. The second partial cascode circuit may be driven by a second bias voltage and may be connected to a power supply voltage. The first partial cascode circuit may reduce phase noise from the ground power supply voltage. The second partial cascode circuit may reduce phase noise from the power supply voltage.

One embodiment may include a system comprising a self-biasing multiplier; and a voltage controlled delay line to receive a first bias voltage and a second bias voltage from the self-biasing multiplier. At least one of the self-biasing multiplier and the voltage controlled delay line may comprise a plurality of partial cascode circuits including at least a first partial cascode circuit and a second partial cascode circuit. The first partial cascode circuit may be driven by a first bias voltage and may be connected to a ground supply voltage. The second partial cascode circuit may be driven by a second bias voltage and may be connected to a power supply voltage. The first partial cascode circuit may reduce phase noise from the ground power supply voltage. The second partial cascode circuit may reduce phase noise the power supply voltage.

One embodiment may include a method to control operational delay of a voltage controlled delay line comprising a plurality of delay cells. The method may comprise converting input voltage from a low-pass filter into low-pass filter transconductance, determining a time constant for each of the plurality of delay cells based on the low-pass filter transconductance and free run transconductance, determining a total time delay based on a plurality of the time constants, and controlling the operational delay based on the total time delay.

Other embodiments are described and claimed.

### BRIEF DESCRIPTION OF THE DRAWINGS

FIG. 1 illustrates one embodiment of a partial cascode differential inverter voltage controlled delay line (VCDL).

FIG. 2 illustrates one embodiment of a VCDL delay cell.

FIG. 3 illustrates one embodiment of a partial cascode circuit.

FIG. 4 illustrates one embodiment of an equivalent circuit of the partial cascode circuit of FIG. 3.

FIG. 5 illustrates one embodiment of a partial cascode circuit.

FIG. 6 illustrates one embodiment of an equivalent circuit of the partial cascode circuit of FIG. 5.

FIG. 7 illustrates one embodiment of an equivalent circuit of the VCDL delay cell of FIG. 2.

FIG. 8 illustrates one embodiment of a time delay graph for the equivalent circuit of FIG. 8.

FIG. 9 illustrates one embodiment of a partial cascode self-biasing multiplier.

FIG. 10 illustrates one embodiment of a DLL circuit.

FIG. 11 illustrates one embodiment of a partial cascode charge pump.

FIG. 12 illustrates one embodiment of a loop filter.

FIG. 13 illustrates one embodiment of a linear model of the DLL circuit of FIG. 10.

FIG. 14 illustrates one embodiment of an equivalent circuit of the DLL circuit of FIG. 10.

FIG. 15 illustrates one embodiment of a graph representing the relationship between output phases and current for the equivalent circuit of FIG. 14.

### DETAILED DESCRIPTION

Numerous specific details have been set forth herein to provide a thorough understanding of the embodiments. It will be understood by those skilled in the art, however, that the embodiments may be practiced without these specific details. In other instances, well-known operations, components and circuits have not been described in detail so as not to obscure the embodiments. It can be appreciated that the specific structural and functional details disclosed herein may be representative and do not necessarily limit the scope of the embodiments.

It is also worthy to note that any reference to “one embodiment” or “an embodiment” means that a particular feature, structure, or characteristic described in connection with the embodiment is included in at least one embodiment. The appearances of the phrase “in one embodiment” in various places in the specification are not necessarily all referring to the same embodiment.

Various embodiments may be directed to a DLL circuit architecture comprising a partial cascode differential inverter VCDL and/or a partial cascode self-biasing multiplier (PCSBM). In contrast a second-order PLL circuit architecture as described in U.S. patent application Ser. No. 11/325,766, referred to above, various embodiments may be directed to a first-order DLL circuit architecture that eliminates the need for a voltage controlled oscillator (VCO), a loop divider, and a band gap circuit.

In various implementations, the partial cascode differential inverter VCDL and the PCSBM may be arranged to provide lower DLL noise, significant PSRR improvement, higher tolerance for lower power supply voltage without requiring a large overhead voltage penalty, increased output impedance to help matching current biasing for the VCDL, and/or enhanced calibration functionality for the VCDL to compensate process variation and store the result in local memory for process compensation.

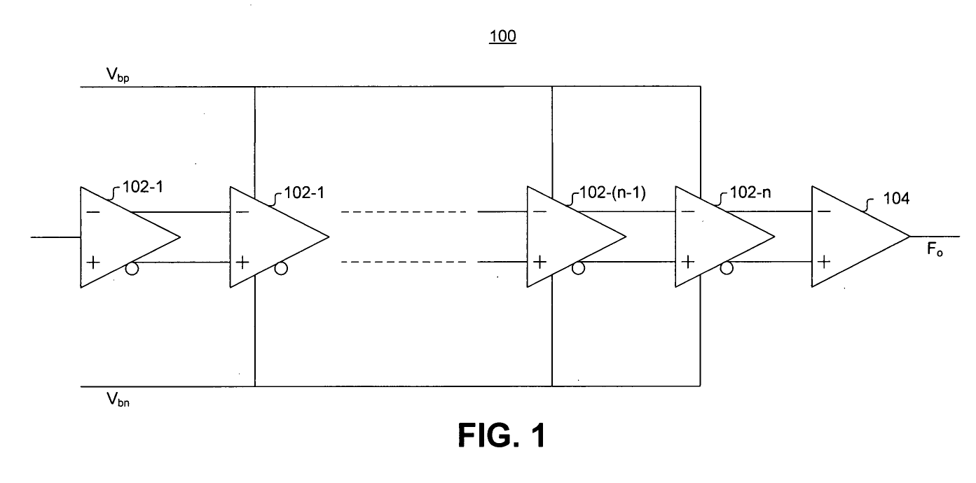

FIG. 1 illustrates one embodiment of a partial cascode differential inverter VCDL 100. In various embodiments, the differential inverter VCDL 100 may be arranged to generate a desired output frequency Fₒ in a DLL circuit architecture. As shown, the partial cascode differential inverter VCDL 100 may comprise a plurality of VCDL delay cells, such as VCDL delay cells 102-1-n, where n may represent any positive integer value. In various implementations, bias voltages (V_{bp}, V_{bn}) may determine the amount of delay for each of the VCDL delay cells 102-1-n within the partial cascode VCDL 100. The bias voltage V_{bp} and the bias voltage V_{bn} may be received, for example, from a PCSBM coupled to the partial cascode differential inverter VCDL 100. It can be appreciated that the number of VCDL delay cells 102-1-n may vary for a given set of design parameters or performance constraints.

In various embodiments, the VCDL delay cells 102-1-n may be arranged such that voltage outputs of a particular VCDL delay cell provide voltage inputs to a subsequent VCDL delay cell. As shown in FIG. 1, for example, voltage outputs of the VCDL delay cell 102-1 provide voltage inputs the VCDL delay cell 102-2. Voltage outputs of the VCDL delay cell 102-2 provide voltage inputs to a subsequent VCDL delay cell (not shown). Voltage outputs of the VCDL delay cell 102-(n-1) provide the voltage inputs to VCDL delay cell 102-n. Voltage outputs from VCDL delay cell 102-n are provided to a differential amplifier 104. The embodiments are not limited, however, to the example depicted by FIG. 1.

In various implementations, a nonlinear VCDL 100 may be employed and the voltage of a first-order low-pass filter (V_{LPF}) is used an input to a PCSBM to control current to the VCDL 100 and a charge pump. Since V_{LPF} is used as input to control current to the partial cascode differential inverter VCDL 100, all differential VCDL delay cells 102-1-n with loaded capacitance (C_{load}) are charged and discharged by differential current sink/source. In various embodiments, the input voltage is converted to a current in a partial cascode self-biasing circuit which is multiplied and mirrored to each fully partial cascode VCDL and charge pump. Each fully partial cascode differential inverter in the VCDL operates in current mode, providing a much wider operating delay range with better PSRR and greater common-mode noise immunity. As a result, improvement in phase noise is achieved.

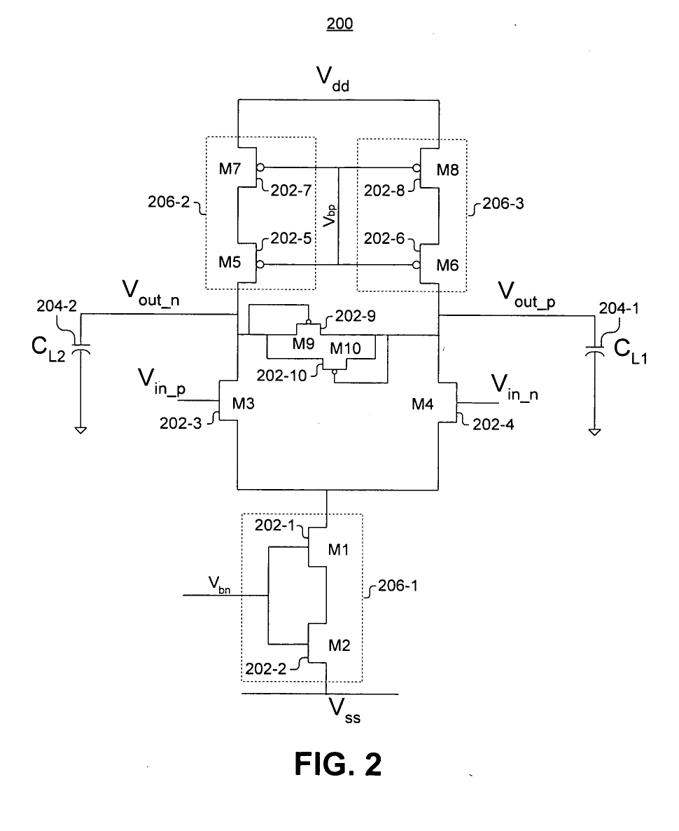

FIG. 2 illustrates one embodiment of a VCDL delay cell 200. In various embodiments, the VCDL delay cell 200 may comprise one of the delay cells 102-1-n implemented by the partial cascode differential inverter VCDL 100 shown in FIG. 1. The embodiments are not limited in this context.

In various embodiments, the VCDL delay cell 200 may comprise a plurality of transistors, such as transistors (M1-M10) 202-1-10, for example. Each transistor may comprise a field effect transistor (FET) such as a junction FET (JFET), a metal-oxide semiconductor FET (MOSFET), or a metal semiconductor FET (MESFET), a bipolar junction transistor (BJT), or any other type of suitable transistor. The transistors may comprise n-type or p-type semiconductor material and may be fabricated using various silicon-based processes such as MOS, complementary MOS (CMOS), bipolar, bipolar CMOS (BiCMOS), and so forth. In one embodiment, the VCDL delay cell 200 may comprise n channel transistors (M1-M4) 202-1-4 and p channel transistors (M5-M10) 202-5-10. The VCDL delay cell 200 also may comprise a plurality of loaded capacitances, such as first loaded capacitance (C_{L1}) 204-1 and second loaded capacitance (C_{L2}) 204-2.

In various embodiments, the VCDL delay cell 200 may comprise a plurality of partial cascode circuits, such as partial cascode circuits 206-1-3, for example. As shown in FIG. 2, a first partial cascode circuit 206-1 comprises n channel transistor (M1) 202-1 and n channel transistor (M2) 202-2. A second partial cascode circuit 206-2 comprises p channel transistor (M5) 202-5 and p channel transistor (M7) 202-7, and a third partial cascode circuit 206-3 comprises p channel transistor (M6) 202-6 and p channel transistor (M8) 202-8. In this embodiment, transistor (M1) 202-1 and transistor (M2) 202-2 of the first partial cascode circuit 206-1 are driven by bias voltage V_{bn}. Transistor (M5) 202-5 and transistor (M7) 202-7 of the second partial cascode circuit 206-2 are driven by bias voltage V_{bp}. Transistor (M6) 202-6 and transistor (M8) 202-8 of the third partial cascode circuit 206-3 also are driven by bias voltage V_{bp}.

In various embodiments, the first partial cascode circuit 206-1 may be connected to a ground supply voltage (Vss). The second partial cascode circuit 206-2 and the third partial cascode circuit 206-3 may be connected to a power supply voltage (Vdd). In such embodiments, the partial cascode circuits 206-1-3 may implement partial cascode topology to both ends (n and p) of the VCDL delay cell 200 to provide a wider operating delay range with increased PSRR and greater common-mode noise immunity without a large overhead voltage penalty. For example, the first partial cascode circuit 206-1 may reduce phase noise and provide improved PSRR with respect to the ground supply voltage (Vss). The second partial cascode circuit 206-2 and the third partial cascode circuit 206-3 may provide reduce phase noise and provide improved PSRR with respect to the power supply voltage (Vdd). In various implementations, the ground supply voltage (Vss) may be a few mV, and the power supply voltage (Vdd) may be 1.8V, for example. The embodiments are not limited, however, to the example depicted by FIG. 2.

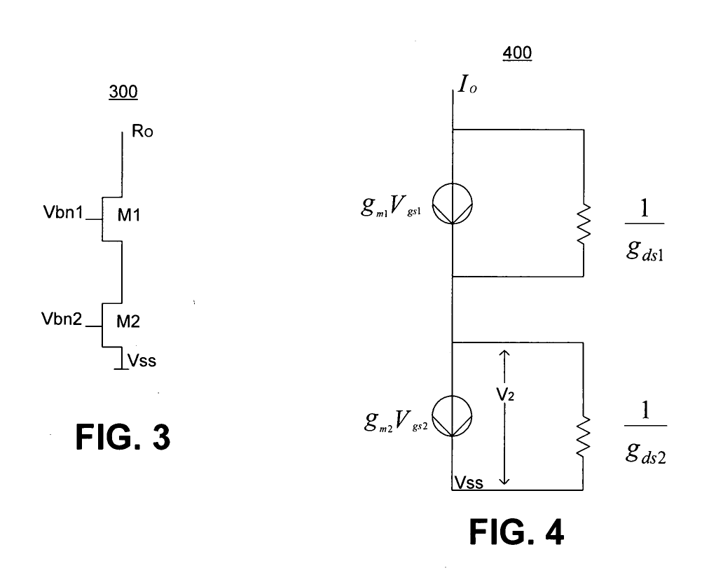

FIG. 3 illustrates one embodiment of a partial cascode circuit 300. In various embodiments, the partial cascode circuit 300 may comprise or be implemented as the first partial cascode circuit 206-1 of the VCDL delay cell 200 shown in FIG. 2. The embodiments are not limited in this context.

In one embodiment, the partial cascode circuit 300 comprises n channel transistor (M1) connected in series to n channel transistor (M2). As shown, the source of transistor (M1) is connected to the drain of transistor (M2). The gate of transistor (M1) is driven by a bias voltage V_{bn1}, and the gate of transistor (M2) is driven by a bias voltage V_{bn2}. In various embodiments, the gate of transistor (M1) and the gate of transistor (M2) may be connected together and driven by a common bias voltage V_{bn} at a single node.

FIG. 4 illustrates one embodiment of an equivalent circuit 400 of the partial cascode circuit 300 shown in FIG. 3. In various embodiments, the following equations may characterize the operation of the equivalent circuit 400.

$${V}_{gs 1} = - {V}_{2 \\}$$

$${V}_{2} = {{I}_{O}}^{*} {r}_{2 ds 2}$$

$${I}_{O} = {g}_{m 1} ( - {{I}_{O}}^{*} {r}_{ds 2} ) + \frac{{V}_{O}}{{r}_{ds 1}} - {I}_{O} \frac{{r}_{ds 2}}{{r}_{ds 1}}$$

$${I}_{O} ( 1 + {g}_{m 1} {r}_{ds 2} + \frac{{r}_{ds 2}}{{r}_{ds 1}} ) = \frac{{V}_{O}}{{r}_{ds 1}}$$

$${R}_{O} = \frac{{V}_{O}}{{I}_{O}}$$

$${R}_{O} = \frac{( 1 + {g}_{m 1} {r}_{ds 2} + \frac{{r}_{ds 2}}{{r}_{ds 1}} )}{{r}_{ds 1}} \approx {g}_{m 1} {r}_{ds 2} {r}_{ds 1}$$

With respect to the foregoing equations, Vₒ is the output voltage, Iₒ is the output current, R, is the output impedance, gₘ₁ is the small-signal transconductance of transistor (M1), r_{ds1} is the drain-to-source channel resistance of transistor (M1), and r_{ds2} is the drain-to-source channel resistance of transistor (M2). Accordingly, it can be demonstrated that the output impedance Rₒ of the partial cascode circuit 300 may be increased by approximately the common gate voltage gain of transistor (M1) multiplied by r_{ds2} without requiring a large overhead voltage penalty. Thus, the partial cascode circuit 400 may be used to reduce noise and improve PSRR, for example.

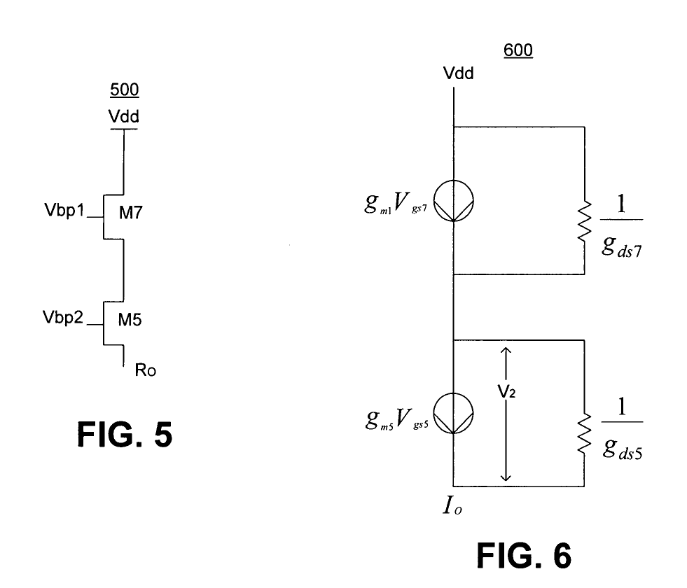

FIG. 5 illustrates one embodiment of a partial cascode circuit 500. In various embodiments, the partial cascode circuit 500 may comprise or be implemented as the second partial cascode circuit 206-2 of the VCDL delay cell 200 shown in FIG. 2. The embodiments are not limited in this context.

In one embodiment, the partial cascode circuit 500 comprises p channel transistor (M7) connected in series to p channel transistor (M5). As shown, the source of transistor (M7) is connected to the drain of transistor (M5). The gate of transistor (M7) is driven by a bias voltage V_{bp1}, and the gate of transistor (M5) is driven by a bias voltage V_{bp2}. In various embodiments, the gate of transistor (M7) and the gate of transistor (M5) may be connected together and driven by a common bias voltage V_{bp} at a single node.

FIG. 6 illustrates one embodiment of an equivalent circuit 600 of the partial cascode circuit 500 shown in FIG. 5. In various embodiments, the following equations may characterize the operation of the equivalent circuit 600.

$${V}_{gs 1} = - {V}_{2}$$

$${V}_{2} = - {{I}_{O}}^{*} {r}_{ds 5 \\}$$

$${I}_{O} = {g}_{m 1} ( - {{I}_{O}}^{*} {r}_{ds 5} ) + \frac{{V}_{O}}{{r}_{ds 7}} - {I}_{O} \frac{{r}_{ds 5}}{{r}_{ds 7}}$$

$${I}_{O} ( 1 + {g}_{m 5} {r}_{ds 5} + \frac{{r}_{ds 5}}{{r}_{ds 7}} ) = \frac{{V}_{O}}{{r}_{ds 7}}$$

$${R}_{O} = \frac{{V}_{O}}{{I}_{O}}$$

$${R}_{O} = \frac{( 1 + {g}_{m 5} {r}_{ds 5} + \frac{{r}_{ds 5}}{{r}_{ds 7}} )}{{r}_{ds 7}} \approx {g}_{m 5} {r}_{ds 5} {r}_{ds 7}$$

With respect to the foregoing equations, Vₒ is the output voltage, Iₒ is the output current, Rₒ is the output impedance, gₘ₅ is the small-signal transconductance of transistor (M5), r_{ds5} is the drain-to-source channel resistance of transistor (M5), and r_{ds7} is the drain-to-source channel resistance of transistor (M7). Accordingly, it can be demonstrated that the output impedance Rₒ of the partial cascode circuit 500 may be increased by approximately the common gate voltage gain of transistor (M5) multiplied by r_{ds7} without requiring a large overhead voltage penalty. Thus, the partial cascode circuit 500 may be used to reduce noise and improve PSRR, for example.

Referring again to FIG. 2, the small signal output impedance of both ends of the VCDL delay cell 200 may be increased by implementing the partial cascode topology. In various implementations, the small signal impedance of the n end of the VCDL delay cell 200 may be increased by the common gate voltage gain of transistor (M1), and the small signal impedance of the p end of the VCDL delay cell 200 may be increase by the common gate voltage gain of transistor (M5). As a result, PSRR may be improved on both ends without requiring a large overhead voltage which can lead to a smaller common input mode range. In addition, improvement in phase noise immunity may be achieved from both the ground supply and the power supply.

As shown in FIG. 2, transistor (M3) 202-3 may receive a voltage input Vin_p, and transistor (M4) 202-4 may receive a voltage input Vin_n. In various embodiments, transistor (M5) 202-5 and transistor (M7) 202-7 may act as a current source for transistor (M3) 202-3. When transistor (M3) 202-3 is not conducting, the supplied current does not pass through transistor (M3) 202-3. Transistor (M6) 202-6 and transistor (M8) 202-8 may act as a current source for transistor (M4) 202-4. When transistor (M4) 202-4 is not conducting, the supplied current does not pass through the transistor (M4) 202-4.

In various embodiments, transistor (M3) 202-3 and transistor (M4) 202-4 may act as switches and determine the actual delay for the VCDL delay cell 200. For example, the delay provided by the VCDL delay cell 200 may be the duration between turning on transistor (M3) 202-3 and turning off transistor (M4) 202-4, and when the voltages Vin_p and Vin_n are equal. At this point, transistors in the next VCDL delay cell may be activated, and output voltages Vout_p and Vout_n of VCDL delay cell 200 may be provided as input voltages Vin_p and Vin_n to the next delay cell.

In various implementations, first loaded capacitance (C_{L1}) 204-1 and second loaded capacitance (C_{L2}) 204-2 charge and discharge to affect the voltages Vin_p and Vin_n, which rise and fall. For instance, when transistor (M3) 202-3 is on and transistor (M4) 202-4 is off, the charges on the first loaded capacitance 204-1 and the second loaded capacitance 204-2 will be affected. In various embodiments, when transistor (M3) 202-3 is on and transistor (M4) 202-4 is off, first loaded capacitance (C_{L1}) 204-1 charges and second loaded capacitance (C_{L2}) 204-2 discharges. The charging of first loaded capacitance (C_{L1}) 204-1 may result in Vout_p changing from low (V_{L}) to high (V_{H}) at saturation. The discharging of second loaded capacitance (C_{L2}) 204-2 may result in Vout_n changing from high (V_{H}) to low (V_{L}). As shown in FIG. 2, transistor (M9) 202-9 and transistor (M10) 202-10 may be arranged to provide a smaller overhead voltage such that transistor (M3) 202-3 and transistor (M4) 202-4 are prevented from moving out off the saturation mode while Vout_n is crossing Vout_p.

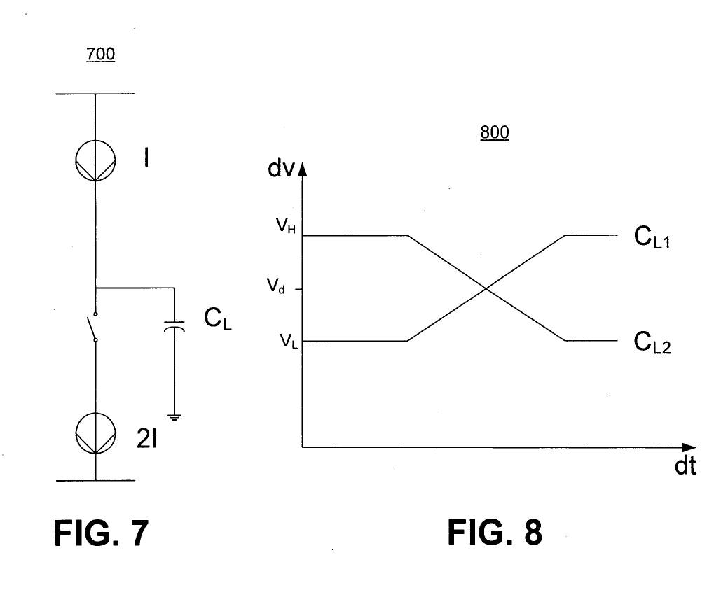

FIG. 7 illustrates one embodiment of an equivalent circuit 700 of VCDL delay cell 200 shown in FIG. 2. As shown, the equivalent circuit 700 comprises a loaded capacitance (C_{L}), which is charged by a current source (I) when a switch is open and discharges to provide a current source (2I) when the switch is closed. FIG. 8 illustrates one embodiment of a time delay graph 800 for the equivalent circuit 700. The embodiments are not limited in this context.

In various embodiments, the following equations may characterize the operation of equivalent circuit 700.

Since the slop of the voltage across C_{L} is

$${V}_{d} = ⅆ {V}_{CL 1} - ⅆ {V}_{CL 2}$$

$$ⅆ {V}_{CL 1} = \frac{{I}_{1}}{{C}_{L1}} ⅆ t$$

$$ⅆ {V}_{CL 2} = \frac{{I}_{2}}{{C}_{L2}} ⅆ t$$

$${V}_{d} = ( {V}_{H} - ⅆ {V}_{CL 1} ) - ( {V}_{L} - ⅆ {V}_{CL 2} )$$

$${V}_{d} = ( {V}_{H} - \frac{{I}_{1}}{{C}_{L 1}} ⅆ t ) - ( {V}_{L} + \frac{{I}_{2}}{{C}_{L 2}} ⅆ t )$$

$${V}_{d} - {V}_{H} + {V}_{L} = \frac{{I}_{1}}{{C}_{L 1}} ⅆ t - \frac{{I}_{2}}{{C}_{L 2}} ⅆ t$$

$${I}_{1} = {I}_{2} = I \\ {C}_{L 1} = {C}_{L 2} = C \\ ( {V}_{H} - {V}_{L} ) - {V}_{d} = \frac{2 I}{C} ⅆ t$$

$$ⅆ t = \frac{( ( {V}_{H} - {V}_{L} ) - {V}_{d} )}{2} \frac{C}{I}$$

$$\frac{ⅆ t}{ⅆ Vlpf} \frac{ⅆ Vlpf}{ⅆ I} = \frac{( ( {V}_{H} - {V}_{L} ) - {V}_{d} )}{2} \frac{C}{\frac{ⅆ I}{ⅆ Vlpf}} \\ \frac{ⅆ t}{ⅆ Vlpf} \frac{ⅆ Vlpf}{ⅆ I} = \frac{( ( {V}_{H} - {V}_{L} ) - {V}_{d} ) C}{2 β ( {V}_{gs} - {V}_{th} )}$$

In various embodiments, VCDL operation may be based on the transconductance of a self-biased multiplier (SBM). For example, where

$$I = \frac{β}{2} {( {V}_{gs} - {V}_{th} )}^{2} and {V}_{gs} = {V}_{lp} in SBM ,$$

a time constant (t) may determined as follows:

$$t = \frac{( ( {V}_{H} - {V}_{L} ) - {V}_{d} ) C}{{g}_{m\_lpf} + {g}_{m\_Free \_runf}}$$

As demonstrated in the foregoing equation, the time constant (t) is a function of low-pass filter (LPF) transconductance (gₘ_{_{—}}_{lpf}) and free run transconductance (gₘ_{_{—}}_{Free}_{_{—}}_{runf}). In various embodiments, gₘ_{_{—}}_{Free}_{_{—}}_{runf} is a fixed frequency and is not a function of LPF voltage, while gₘ_{_{—}}_{lpf} is dynamic.

In various implementations, the VCDL operational delay may be based on a total time delay (7) comprising time constants for a plurality of VCDL delay cells. For example, in a VCDL comprising three VCDL delay cells, the total time delay (T) may be determined as follows:

$$T = {t}_{1} + {t}_{2} + {t}_{3}$$

$$T = \frac{ⅆ {t}_{1}}{ⅆ Vlpf} \frac{ⅆ Vlpf}{ⅆ I} + \frac{ⅆ {t}_{2}}{ⅆ Vlpf} \frac{ⅆ Vlpf}{ⅆ I} + \frac{ⅆ {t}_{3}}{ⅆ Vlpf} \frac{ⅆ Vlpf}{ⅆ I}$$

$$T = \frac{N ( ( {V}_{H} - {V}_{L} ) - {V}_{d} ) C}{{g}_{m\_lpf} + {g}_{m\_Free \_runf}}$$

In various embodiments, gₘ_{_{—}}_{Free}_{_{—}}_{runf} would be multiplied by a multiplier circuit in order to have tuning condition on the VCDL for N number of delay cells.

Based on the foregoing, in various embodiments, the total delay (D) of N stage and the gain for the VCDL transfer function (K_{VCDL}) may be expressed as follows:

$$D = M \times T = \frac{N ( ( {V}_{H} - {V}_{L} ) - {V}_{d} ) C}{( {g}_{m\_lpf} + {Mg}_{m\_Free \_runf} )}$$

$${K}_{VCDL} = \frac{ⅆ D}{ⅆ {V}_{lpf}} = \frac{N ( ( {V}_{H} - {V}_{L} ) - {V}_{d} ) C}{{β}_{m\_lpf}}$$

The embodiments, however, are not limited in this context.

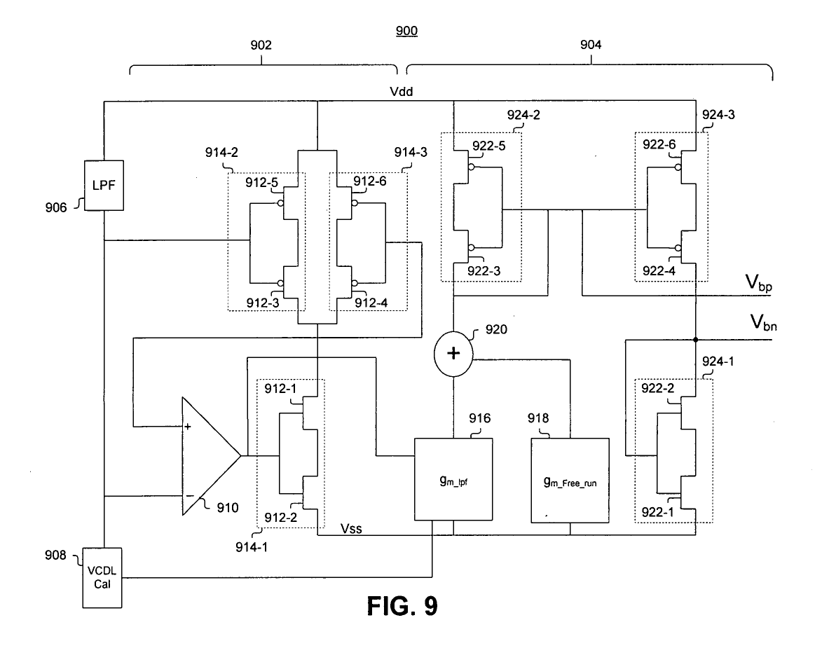

FIG. 9 illustrates one embodiment of a PCSBM 900. In various embodiments, the PCSBM 900 may be arranged to provide bias voltage V_{bp} and bias voltage V_{bn} to the partial cascode differential inverter VCDL 100 of FIG. 1. For example, the PCSBM 900 may convert the input voltage from a low-pass filer (LPF) to current which is multiplied and mirrored to each fully partial cascode VCDL. The embodiments are not limited in this context.

As shown in FIG. 9, the PCBM 900 may comprise bias generator portion 902 and current multiplier portion 904. In various implementations, the bias generator portion 902 may receive input from LPF 906 and provide output to current multiplier portion 904. The LPF 906 also may provide input to VCDL calibration unit 908, which provides input to current multiplier portion 904.

In various embodiments, the bias generator portion 902 of the PCSBM 900 may comprise a differential amplifier 910 and plurality of transistors, such as transistors 912-1-6, for example. In one embodiment, for example, the bias generator portion 902 of the PCSBM 900 may comprise n channel transistors 912-1 and 912-2 and p channel transistors 912-3-6. Each transistor may comprise a FET, BJT, or any other type of suitable transistor.

In various embodiments, the bias generator portion 902 of the PCSBM 900 may comprise a plurality of partial cascode circuits, such as partial cascode circuits 914-1-3, for example. As shown, partial cascode circuit 914-1 comprises n channel transistor 912-1 and n channel transistor 912-2, partial cascode circuit 914-2 comprises p channel transistor 912-3 and p channel transistor 912-5, and partial cascode circuit 914-3 comprises p channel transistor 912-4 and p channel transistor 912-6.

In various embodiments, the partial cascode circuit 914-1 may be connected to a ground supply voltage (Vss). The partial cascode circuit 914-2 and partial cascode circuit 914-3 may be connected to a power supply voltage (Vdd). In such embodiments, the partial cascode circuits 914-1-3 may implement partial cascode topology to provide a wider operating delay range with increased PSRR and greater common-mode noise immunity without a large overhead voltage penalty. For example, the partial cascode circuit 914-1 may reduce phase noise and provide improved PSRR with respect to the ground supply voltage (Vss). The partial cascode circuit 914-2 and the partial cascode circuit 914-3 may reduce phase noise and provide improved PSRR with respect to the power supply voltage (Vdd). In various implementations, the ground supply voltage (Vss) may be a few mV, and the power supply voltage (Vdd) may be 1.8V, for example.

In various embodiments, the current multiplier portion 904 of the PCSBM 900 may comprise a first transconductance (gₘ_{_{—}}_{lpf}) 916, a second transconductance (gₘ_{_{—}}_{Free}_{_{—}}ᵣᵤₙ) 918, a summing unit 920, and a plurality of transistors, such as transistors 922-1-6, for example. In one embodiment, for example, the current multiplier portion 904 of the PCSBM 900 may comprise n channel transistors 922-1 and 922-2 and p channel transistors 922-3-6. Each transistor may comprise a FET, BJT, or any other type of suitable transistor.

In various embodiments, the current multiplier portion 904 of the PCSBM 900 may comprise a plurality of partial cascode circuits, such as partial cascode circuits 924-1-3, for example. As shown, partial cascode circuit 924-1 comprises n channel transistor 922-1 and n channel transistor 922-2, partial cascode circuit 924-2 comprises p channel transistor 922-3 and p channel transistor 922-5, and partial cascode circuit 924-3 comprises p channel transistor 922-4 and p channel transistor 922-6.

In various embodiments, the partial cascode circuit 924-1 may be connected to a ground supply voltage (Vss). The partial cascode circuit 924-2 and partial cascode circuit 924-3 may be connected to a power supply voltage (Vdd). In such embodiments, the partial cascode circuits 924-1-3 may implement partial cascode topology to provide a wider operating delay range with increased PSRR and high common-mode noise immunity without a large overhead voltage penalty. For example, the partial cascode circuit 924-1 may reduce phase noise and provide improved PSRR with respect to the ground supply voltage (Vss). The partial cascode circuit 924-2 and the partial cascode circuit 924-3 may reduce phase noise and provide improved PSRR with respect to the power supply voltage (Vdd). In various implementations, the ground supply voltage (Vss) may be a few mV, and the power supply voltage (Vdd) may be 1.8V, for example.

In various implementations, the partial cascode circuits 914-1-3 and partial cascode circuits 924-1-3 of the PCSBM 900 may comprise partial cascode topology to provide a wider operating delay range with increased PSRR and greater common-mode noise immunity without a large overhead voltage penalty. In various embodiments, the bias generator portion 902 and the current multiplier portion 904 of the PCSBM 900 may be arrange to interface with each other and with a partial cascode differential inverter VCDL, such as partial cascode differential inverter VCDL 100. In such embodiments, the partial cascode differential inverter VCDL 100 and the PCSMB 900 may implement fully partial cascode topology to ensure improved PSRR.

In various embodiments, if the voltage-controlled current sources have voltage to current linearity, then the transfer relationship may be expressed as follows:

$${I}_{d} = {g}_{m} ( {V}_{LPF} ) + {g}_{m} ( {V}_{Free\_run} )$$

$$where$$

$${g}_{m\_SB} = \frac{ⅆ {I}_{1}}{ⅆ {V}_{lpf}}$$

$${V}_{gs} = {V}_{lpf}$$

$$I = \frac{β}{2} {( {V}_{gs} - {V}_{th} )}^{2}$$

$${g}_{m\_SB} = \frac{ⅆ {I}_{1}}{ⅆ {V}_{lpf}}$$

$${g}_{m\_ SBM} = \frac{ⅆ {I}_{1}}{ⅆ {V}_{lpf}} + \frac{ⅆ {I}_{2}}{ⅆ {V}_{Free\_run}}$$

$${g}_{m\_ SBM} = {g}_{m\_lpf} + ( M \times {g}_{m\_Free \_runf} )$$

With respect to the foregoing equations, gₘ_{_{—}}_{SB} is the self-bias transconductance, and gₘ_{_{—}}_{SB} is the transconductance of the self-biasing multiplier transconductance. In various embodiments, the input LPF voltage is used to control current to the partial cascode differential inverter VCDL 100 and a charge pump.

In various embodiments, the PCSBM 900 may provide several multiplication ranges, such as (1 to X) multiplication ranges. In one embodiment, for example, the PCSBM 900 may provide 4-bit control and 16 multiplication ranges. In various implementations, the PCSBM 900 may achieve high tolerance for process variations by calibrating the current range in the PCSBM for a specific operational frequency without the requirement of a band gap circuit. In addition, the partial cascode topology in the analog cells provides an improvement in PSRR, without requiring a large overhead voltage. As a result, the PCSBM 900 may provide better phase noise (e.g., VCDL output jitter) and wider operation for the same silicon size.

In various implementations, the PCSBM 900 provides the necessary bias with lower sensitivity to temperature changes, process variations, and voltage drop on the power supply, while providing better PSRR and self-calibration current setting range with lower VCDL gain (K_{VCDL}). The PCSBM 900 may be arranged to provide lower DLL noise, significant PSRR improvement, higher tolerance for lower power supply voltage without requiring a large overhead voltage penalty, increased output impedance to help matching current biasing for the VCDL, and/or enhanced calibration functionality for the VCDL to compensate process variation and store the result in local memory for process compensation.

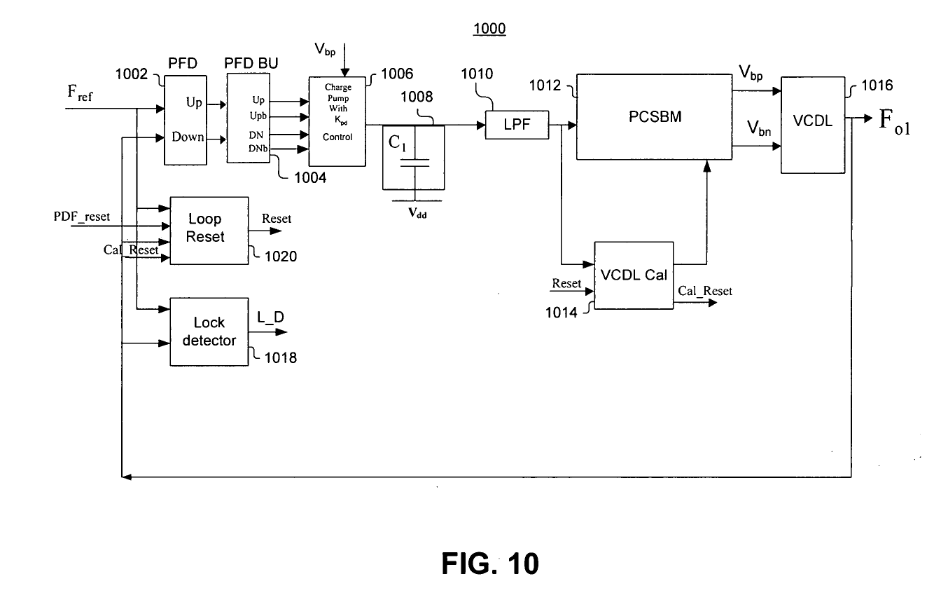

FIG. 10 illustrates one embodiment of a DLL circuit 1000. In various embodiments, the DLL circuit 1000 may comprise PFD 1002, PFD buffer 1004, charge pump 1006, loop filter 1008 including capacitor (C1), LPF 1010 (e.g., 1/RC circuit), PCSBM 1012, VCDL calibration unit 1014, VCDL 1016, lock detect 1018, and loop reset 1020. The embodiments are not limited in this context.

In various embodiments, the PCSBM 1012 may comprise or be implemented by the PCSBM 900 of FIG. 9, and the VCDL 1016 may comprise or be implemented by the partial cascode differential inverter VCDL 100 of FIG. 1. In such embodiments, the DLL circuit 1000 may be arranged to provide lower DLL noise, significant PSRR improvement, higher tolerance for lower power supply voltage without requiring a large overhead voltage penalty, increased output impedance to help matching current biasing for the VCDL, and/or enhanced calibration functionality for the VCDL to compensate process variation and store the result in local memory for process compensation.

In various implementations, the PFD 1002 determines the phase and frequency difference between a reference frequency F_{ref} and the output frequency signal Fₒ from the frequency divider VCDL 1016. If a difference is detected, the PFD 1002 sends error signals Up, Down to the charge pump 1006. The duration of the error signals may depend on the amount of phase and frequency error detected by the PFD 1002.

In various embodiments, the charge pump 1006 receives the error signals Up, Down and a reference bias voltage V_{bp} which control the charge pump output current. The output current generated by the charge pump 1006 charges or discharges the capacitor (C₁) of loop filter 1008 to a voltage level V_{LPF}. The voltage V_{LPF} is used as a reference for the PCSBM 1012 to generate reference signals V_{bp}, V_{bn} to control the output frequency Fₒ of the VCDL 1016.

In various implementations, the charge pump 1006 may comprise a partial cascode charge pump having a common current node and high output impedance architecture providing improved current matching between sink and source currents at the output. Better matching in sink and source current improves phase noise and jitter as well as tolerance of process and temperature variations in matching the sink and source current outputs. In addition, the locking range is not significantly reduced, and the locking time may be much lower in comparison to an architecture that uses a band gap to provide a steady state current reference to the charge pump 1006 because the charge pump 1006 is biased with the dynamic current mode PCSBM 1012. The embodiments are not limited in this context.

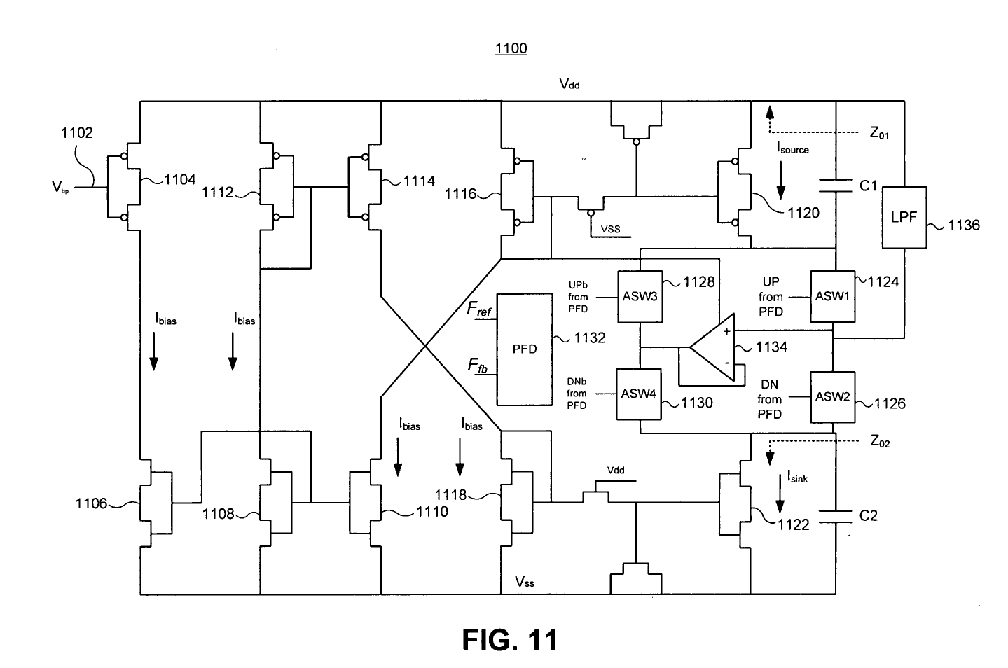

FIG. 11 illustrates one embodiment of a partial cascode charge pump circuit 1100. In various embodiments, the charge pump circuit 1100 may be implemented as the charge pump 1006 of FIG. 10. The embodiments are not limited in this context. For example, the charge pump 1006 may comprise any embodiment of a partial cascode charge pump as described in co-pending U.S. patent application Ser. No. 11/186,000, referred to above.

In various embodiments, the charge pump circuit 1100 comprises a common bias voltage node 1102 where a single bias voltage V_{bp} may be applied to the charge pump circuit 1100 to generate output source and sink currents I_{source}, Iₛᵢₙₖ. In operation, the charge pump circuit 1100 may provide well-matched output source and sink currents I_{source}, Iₛᵢₙₖ based on the single node bias voltage V_{bp} reference applied to node 1102. Furthermore, the partial cascode transistor structure provides improved output impedance Z₀₁, Z₀₂ without a significant increase in overhead voltage.

As illustrated, the charge pump circuit 1100 may employ partial cascode circuitry as described above. Partial cascode transistors 1104 generate bias current I_{bias} based on input bias voltage V_{bp} applied to the common gates of transistors 1104 at node 1102. In one embodiment, the common gates of transistors 1104 form the common bias voltage node 1102. The bias current I_{bias} is mirrored by partial cascode transistors 1106. The gates of partial cascode transistors 1106 are connected to the gates of partial cascode transistors 1108, 1110. This mechanism forms a current mirror structure where each of the partial cascode transistors 1112, 1114, 1116 drive bias current I_{bias} through respective current paths. The bias current I_{bias} through each of the current paths is substantially the same and is a function of matching the partial cascode transistors 1104, 1106, 1108, 1110, 1114, 1116, and 1118. The current mirror structure also drives source and sink currents I_{source}, Iₛᵢₙₖ through partial cascode output transistors 1120. Similarly, Iₛᵢₙₖ is driven through partial cascode output transistors 1122. It can be appreciated that under matched transistor conditions: I_{bias}=I_{source}=Iₛᵢₙₖ.

In one embodiment, circuit 1100 may comprise analog switches 1124, 1126, 1128, and 1130 arranged in a bridge configuration. The inputs of analog switches 1124, 1128 are connected to the current source I_{source} of the charge pump circuit 1100. The output of analog switch 1124 is connected to the input of analog switch 1126, and the output of analog switch 1128 is connected to the input of analog switch 1130. The outputs of analog switches 1126, 1130 are connected to the sink current Iₛᵢₙₖ of the charge pump circuit 1100. The analog switches 1124, 1126, 1128, and 1130 are controlled by outputs UP, DN, UPb, DNb, respectively, of a PFD 1132.

In operation, the charge pump circuit 1100 sources and sinks currents I_{source}, Iₛᵢₙₖ. In one embodiment, source current I_{source} is driven to the inputs of analog switches 1124, 1128. Sink current Iₛᵢₙₖ is driven from analog switches 1126, 1130. Operational amplifier 1134 is biased in the common mode to provide matching current capability at its output, where it drives a dummy load. In one embodiment, a low pass filter 1136 feeds a VCDL, for example.

In various embodiments, the architecture of charge pump circuit 1100 enforces the matching condition between sink and source currents I_{source}, Iₛᵢₙₖ. The charge pump circuit 1100 also provides better output current performance while source and sink current driver circuits 1120, 1122 remain in saturation mode over a wider range of operation and provides better performance control of phase noise or jitter and phase stability due to better matched source and sink currents I_{source}, Iₛᵢₙₖ. The charge pump circuit 1100 also provides better tolerance to variations in temperature and semiconductor fabrication process without any band gap reference voltage.

Referring again to FIG. 10, when the loop is locked, a combination of PFD 1002 and charge-pump 1006 self-correction may generate a voltage ripple on the input of VCDL 1016, which leads to a change in the output clock as jitter. The jitter may be defined as the deviation in the clock output from an ideal position expressed as a percentage of frequency deviation. The largest single contributor to jitter is power supply noise on a DLL supply inputs. Such noise appears on the output as jitter and manifests as ground bounce (v=L(di/dt)) and V_{DD} noise. The threshold voltage of transistors may change because of a change in ground potential or noise on the supply voltage. Because of phase jitter, the edges of the signal are spread over an interval of time.

The jitter may comprise for example, cycle-to-cycle jitter, period jitter, and long term jitter. Cycle-to-cycle jitter may be defined as the change in the output of a clock from a corresponding position in the previous cycle. Period jitter may be defined as the maximum change in clock output from an ideal position. An example of period jitter is where the rising edge of the clock comes before data on the bus is valid. As a result, a processor or memory can receive inaccurate data, which leads to system malfunction. Long term jitter may be defined as the maximum change in clock output from an ideal position over many cycles, such as an interval of 10 to 20 μsec for graphics applications.

In various implementations, the ripple effect on the LPF 1010 at the input of VCDL 1016 may be reduced by having control on the current source and sink. By reducing VCDL gain, the ripple on the input of the VCDL 1016 has less of an effect on the output frequency. In some cases, however, this may reduce the range of frequencies that the DLL can lock up.

Jitter at the output of the VCDL 1016 may be improved by reducing the bandwidth of the loop filter 1008 bandwidth. In some cases, this may increase chip real estate (c=I(dv/dt)). In various implementations, reducing the gain of the PFD 1002 by reducing I_{Pump} leads to improvement of jitter at the VCDL 1016. In some cases, by reducing the Iₚᵤₘₚ, substrate noise might become more of a factor.

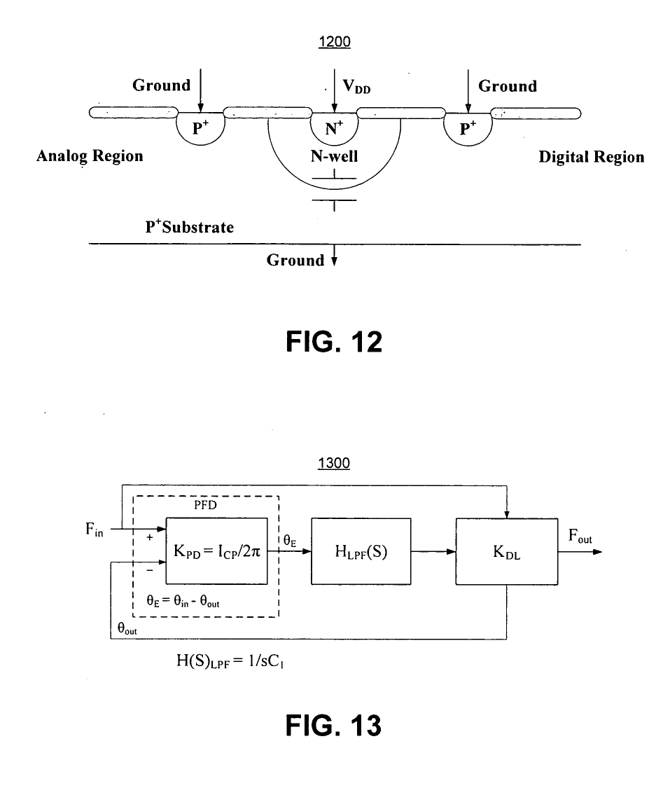

FIG. 12 illustrates one embodiment of a LPF 1200. In various embodiments, the LPF 1200 may be implemented as the LPF 1010 of FIG. 10. The embodiments are not limited in this context. For example, the design layout for the LPF 1200 may be applicable to implement other capacitances such as in a loop filter (e.g., loop filter 1008) or in a charge pump (e.g., charge pump 1006, 1100).

In various embodiments, the LPF 1200 may implement features for minimizing noise in analog circuits. As shown, the LPF 1200 may comprise a PMOS cap in an N-well to prevent substrate coupling noise. The N-well may be connected directly to ground. The use of the N-well between the P⁺ connections increases the resistive impedance of the substrate, which is located between the analog and digital regions, due to graded substrate doping. In addition, the N-well, which is connected to V_{DD}, operates as a bypass capacitor to help lower the voltage fluctuation

$$Δ V = \frac{I \times Δ t}{( {C}_{N \text{-} well} )}$$

and noise

$$\frac{1}{( 1 + SRC )}$$

on V_{DD}. As such, the combination of metal impedance of the power stripe and C_{N-well} provide a low pass filter 1200 for lowering the noise at the input of the DLL V_{DD} analog circuitry. In various implementations, the value ω_{N} may be set to about a decade below F_{REF} by setting ((I_{CH}×K_{DL})/C)≦π/5.

In order to further reduce the substrate coupling noise to an absolute minimum, two levels of guard ring may be used around the filter capacitor. In various implementations, the digital and analog circuitry may be separated by guard rings and wells connected to the power supply voltages. In addition, two levels of guard rings may be used when implementing a charge pump (e.g., charge pump 1006, 1100). The embodiments are not limited in this context.

While the DLL circuit 1000 illustrated in FIG. 10 may be generally represented as a nonlinear system for the purpose of investigating its dynamic behavior, linear approximation may be useful to understand the functionality and trade-offs in the DLL circuit 1000.

FIG. 13 illustrates one embodiment of a linear model 1300 of DLL circuit 1000 of FIG. 10. As shown, K_{PD}=I_{CP}/2π (amp/radian) may represent the gain of a PFD (e.g., PFD 1002). In various embodiments, the open loop transfer function is:

$$H ( S ) = \frac{{ϕ}_{Out} ( s )}{{ϕ}_{In} ( s )} = \frac{{I}_{CP}}{{T}_{REF}} {K}_{LPF} {K}_{DL} \qquad ( 1 )$$

where φ_{IN} is phase error of F_{REF}, and φₒᵤₜ is the delay requirement to bring Fₒᵤₜ in phase with the input frequency. K_{LPF} is defined as the transfer function of the low pass filter (LPF) and

$${K}_{DL} = \frac{{t}_{Max\_delay} - {t}_{Min\_delay}}{{{V}_{Max\_input \_VVDL}}^{-} {V}_{Min\_input \_VVDL}}$$

is the gain for the VCDL transfer function in seconds per volt. V_{Max}_{_{—}}ᵢₙₚᵤₜ_{_{—}}_{VVDL} and V_{Min}_{_{—}}ᵢₙₚᵤₜ_{_{—}}_{VVDL} are maximum and minimum input voltage for maximum and minimum (t_{MAX}_{_{—}}_{delay}−t_{Min}_{_{—}}_{delay}) output delay of VCDL.

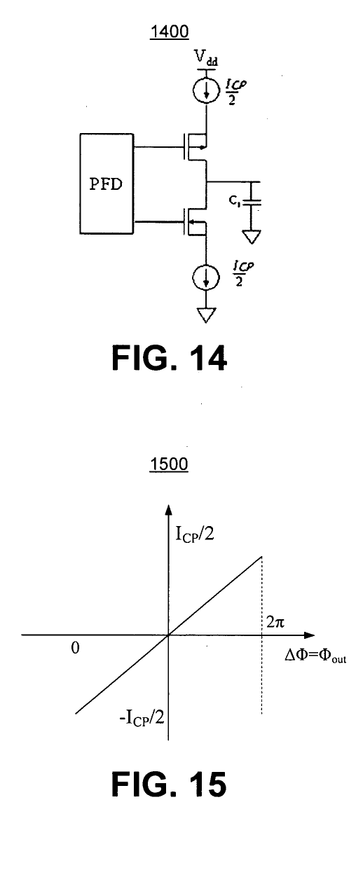

FIG. 14 illustrates one embodiment of an equivalent circuit 1400 of the DLL circuit 1000 of FIG. 10.

FIG. 15 illustrates one embodiment of a graph 1500 representing the relationship between output phases to current for the equivalent circuit 1400 of FIG. 14.

Substituting the transfer function for the LPF,

$${K}_{LPF} = \frac{1}{{SC}_{1}}$$

in to (1) yields:

$$H ( s ) = {I}_{CP} {K}_{DL} \frac{1}{{SC}_{1}} {F}_{REF} .$$

In order to simplify the open-loop transfer function, the expression for H(s) may be put in a standard form as follows:

$${D}_{O} ( s ) = {H}_{Open} ( s ) ( {D}_{I} ( s ) - {D}_{O} ( s ) )$$

$$\frac{{D}_{O} ( s )}{{D}_{I} ( s )} = \frac{{H}_{Open} ( s )}{1 + {H}_{Open} ( s )}$$

$$\frac{{D}_{O} ( s )}{{D}_{I} ( s )} = \frac{1}{1 + \frac{1}{{H}_{Open} ( s )}}$$

$$\frac{{D}_{O} ( S )}{{D}_{I} ( S )} = \frac{1}{1 + \frac{{SC}_{1}}{{I}_{P} {K}_{DL} {F}_{REF}}}$$

The pole may be defined as:

$$P = \frac{{C}_{1} {I}_{CP} {K}_{DL} {F}_{REF}}{{C}_{1}}$$

Next, the step response may be used to determine instantaneous change in output phase. The transmission delay Dₒ(s) can be defined as:

$${D}_{O} ( S ) = \frac{Δ {D}_{I} ( S ) / S}{1 + \frac{{SC}_{1}}{{I}_{CP} {K}_{DL} {F}_{REF}}}$$

$${D}_{O} ( S ) = \frac{Δ {D}_{I} ( S ) / S}{1 + {Sω}_{1 N}}$$

$${D}_{O} ( S ) = \frac{{V}_{O}}{{V}_{In}} = \frac{1}{1 + {Sω}_{N}}$$

The voltage rise Vₒ up at LPF can be defined as:

$${V}_{O} = {V}_{In} ( 1 - {ⅇ }^{\frac{- t}{ω N}} )$$

Where Vo=0.1Vₗₙ t₁=0.11 ω_{N}, and for Vo=0.9Vₗₙ t₂=2.3 ω_{N}

Therefore, the transmission delay time on LPF or locking time may be:

$${t}_{d =} {t}_{2} - {t}_{1 \\}$$

$${t}_{d} = \frac{2.2 \times {C}_{1}}{{I}_{CP} {K}_{DL} {F}_{REF}}$$

And the loop bandwidth can be defined as:

$${ω}_{n} = \frac{{I}_{CP} {K}_{DL} {F}_{REF}}{{C}_{1}}$$

$${F}_{N} = \frac{{I}_{P} {K}_{DL} {F}_{REF}}{2 π {C}_{1}}$$

While certain features of the embodiments have been illustrated as described herein, many modifications, substitutions, changes and equivalents will now occur to those skilled in the art. It is therefore to be understood that the appended claims are intended to cover all such modifications and changes as fall within the true spirit of the embodiments.

1. An apparatus comprising:
a delay locked loop circuit comprising a plurality of partial cascode circuits, said plurality of partial cascode circuits including at least a first partial cascode circuit and a second partial cascode circuit, said first partial cascode circuit to be driven by a first bias voltage and to be connected to a ground supply voltage, said second partial cascode circuit to be driven by a second bias voltage and to be connected to a power supply voltage,
wherein said first partial cascode circuit is to reduce phase noise from said ground power supply voltage and said second partial cascode circuit is to reduce phase noise from said power supply voltage.

2. The apparatus of claim 1, wherein said first partial cascode is to provide an output impedance to reduce said phase noise from said ground supply voltage.

3. The apparatus of claim 1, wherein said second partial cascode is to provide an output impedance to reduce said phase noise from said power supply voltage.

4. The apparatus of claim 1, wherein said first partial cascode circuit comprises a plurality of n channel transistors and said second partial cascode comprises a plurality of p channel transistors.

5. The apparatus of claim 1, wherein said plurality of partial cascode circuits comprises a third partial cascode circuit to be driven by said second bias voltage.

6. The apparatus of claim 5, wherein said third partial cascode circuit comprises a plurality of p channel transistors.

7. The apparatus of claim 1, said delay locked loop circuit comprising a voltage controlled delay line including said plurality of partial cascode circuits.

8. The apparatus of claim 7, said voltage controlled delay line comprising a plurality of delay cells.

9. The apparatus of claim 8, wherein at least one of said plurality of delay cells is to provide voltage outputs as voltage inputs to another one of said plurality of delay cells.

10. The apparatus of claim 7, said voltage controlled delay line to receive said first bias voltage and said second bias voltage from a self-biasing multiplier.

11. The apparatus of claim 7, said voltage controlled delay line comprising a first loaded capacitance and a second loaded capacitance to charge and discharge to provide a delay.

12. The apparatus of claim 1, said delay locked loop circuit comprising a self-biasing multiplier including said plurality of partial cascode circuits.

13. The apparatus of claim 12, said self-biasing multiplier comprising a bias generator portion, said bias generator portion comprising said plurality of partial cascode circuits.

14. The apparatus of claim 12, said self-biasing multiplier comprising a current multiplier portion, said current multiplier portion comprising said plurality of partial cascode circuits.

15. The apparatus of claim 12, said self-biasing multiplier to provide said first bias voltage and said second bias voltage to a voltage controlled delay line.

16. A system comprising:
a self-biasing multiplier; and
a voltage controlled delay line to receive a first bias voltage and a second bias voltage from said self-biasing multiplier, at least one of said self-biasing multiplier and said voltage controlled delay line comprising:
a plurality of partial cascode circuits including at least a first partial cascode circuit and a second partial cascode circuit, said first partial cascode circuit to be driven by a first bias voltage and to be connected to a ground supply voltage, said second partial cascode circuit to be driven by a second bias voltage and to be connected to a power supply voltage,
wherein said first partial cascode circuit is to reduce phase noise from said ground power supply voltage and said second partial cascode circuit is to reduce phase noise from said power supply voltage.

17. The system of claim 16, wherein said plurality of partial cascode circuits comprises a third partial cascode circuit to be driven by said second bias voltage.

18. The system of claim 16, said self-biasing multiplier may to provide a plurality of multiplication ranges to calibrate a current range for a specific operational delay of said voltage controlled delay line.

19. The system of claim 18, wherein said plurality of multiplication ranges comprises 16 multiplication ranges.

20. A method to control operational delay of a variable controlled delay line comprising a plurality of delay cells, the method comprising:
converting input voltage from a low-pass filter into low-pass filter transconductance;
determining a time constant for each of said plurality of delay cells based on said low-pass filter transconductance and free run transconductance;
determining a total time delay based on a plurality of said time constants; and
controlling said operational delay based on said total time delay.
